(19) United States
(12) Patent Application Publication
(10) Pub. No.: US 2025/0255163 A1
(43) Pub. Date: Aug. 7, 2025

(54) LIGHT EMITTING DISPLAY DEVICE

(71) Applicant: LG Display Co., Ltd., Seoul (KR)

(72) Inventors: MunChae YOON, Paju-si (KR); Seonghwan HWANG, Paju-si (KR)

(21) Appl. No.: 19/001,187

(22) Filed: Dec. 24, 2024

(30) Foreign Application Priority Data
Feb. 7, 2024 (KR) 10-2024-0019266

(51) Int. Cl. H10K 59/80; H10K 59/38

(52) U.S. Cl. CPC H10K 59/8792; H10K 59/38

(57) ABSTRACT

A light emitting display according to the present disclosure includes: a substrate; a display area disposed at middle portion of the substrate and including an emission area and a non-emission area; a first color filter disposed in the emission area and including at least one of a first color layer, a second color layer and a third color layer; a second color filter disposed in the non-emission area and including at least one of the first color layer, the second color layer and the third color layer; a driving element disposed on the second color filter in the non-emission area; and a light emitting element disposed on the first color filter in the emission area and connected to the driving element.

### CROSS-REFERENCE TO RELATED APPLICATIONS

This application claims the benefit of the Republic of Korea Patent Application No. 10-2024-0019266 filed on Feb. 7, 2024, which are hereby incorporated by reference in its entirety.

### BACKGROUND

### Technical Field

The present disclosure relates to a light emitting display device having a structure for preventing the external light reflection.

### Description of the Related Art

The light emitting display device, one of the self-luminance display device, may have a structure in which a plurality of pixels including light emitting diode are arrayed in a matrix manner. Each pixel may include an emission area providing light for representing video image, and a non-emission area including driving elements. As metal material may be patterned in the non-emission area, external lights incident from outside may be reflected. As the result, the video images from the emission area may not be properly perceived by the reflected external light.

### BRIEF SUMMARY

In view of the various technical problems in the related art, the inventors of the present disclosure have provided various embodiments of a light emitting display device with a structure designed to prevent display quality deterioration caused by external light reflection. Various embodiments of the present disclosure provide a light emitting display device that improves display quality by suppressing reflection of external light from the non-emission area where metal materials may be disposed.

A light emitting display device according to the present disclosure comprises: a substrate; a display area disposed at middle portion of the substrate and including an emission area and a non-emission area; a first color filter disposed in the emission area and including at least one of a first color layer, a second color layer and a third color layer; a second color filter disposed in the non-emission area and including at least one of the first color layer, the second color layer and the third color layer; a driving element disposed on the second color filter in the non-emission area; and a light emitting element disposed on the first color filter in the emission area and connected to the driving element.

In one aspect, each of the first color layer, the second color layer and the third color layer include color material having different color wavelength band from each other.

In one aspect, the first color layer includes color material having a red wavelength band. The second color layer includes color material a green wavelength band. The third color layer includes color material a blue wavelength band.

In one aspect, the second color filter includes a blue color layer and a red color layer sequentially stacked.

In one aspect, the second color filter includes a blue color layer and a green color layer sequentially stacked.

In one aspect, the second color filter includes a red color layer and a green color layer sequentially stacked.

In one aspect, the second color filter includes a red color layer, a green color layer and a blue color layer sequentially stacked.

In one aspect, the light emitting display device further comprises: a transparent insulating layer disposed under the first color filter in the emission area; and a scattering pattern disposed under the transparent insulating layer.

In one aspect, the scattering pattern includes a color material same as the first color filter.

In one aspect, the transparent insulating layer has a refractive index higher than the first color filter.

In one aspect, the first color filter has a refractive index of 1.5. The transparent insulating layer has a refractive index of 1.9.

In one aspect, the driving element includes a repair portion. The second color filter disposed at an area corresponding to the repair portion includes any one of the first color layer, the second color layer and the third color layer.

In one aspect, the color layer disposed at the area corresponding to the repair portion includes a color material having same wavelength with a laser irradiated to the repair portion.

In one aspect, the light emitting display device further comprises: a buffer layer disposed on the second color filter; a thin film transistor formed on the buffer layer; a passivation layer on the thin film transistor; the first color filter disposed on the passivation layer; a planarization layer disposed on the passivation layer and the first color filter; a pixel electrode disposed on the planarization layer, connected to the thin film transistor and corresponding to the emission area; a bank disposed on the pixel electrode to define the emission area; an emission layer on the pixel electrode and the bank; and a common electrode disposed on the emission layer.

In one aspect, the light emitting display device further comprises: a scattering pattern disposed at same layer with the second color filter and under the first color filter, and having same color with the first color filter.

The light emitting display device according to the present disclosure may include at least one color layer (in some examples, two-color layers) disposed in a non-emission area, thereby suppressing reflection of external light by metal material disposed in the non-emission area. Accordingly, the present disclosure may provide a light emitting display device in which the deterioration of display quality due to the external light reflection in the non-emission area may be prevented. Even though high luminance is not provided from the emission area in order to overcome external light reflection occurring in the non-emission area, high-quality video information may be provided. As a result, the present disclosure may provide bright and clear images with the same power consumption, or images of the same quality with lower power consumption than before. Accordingly, the present disclosure may provide a light emitting display device with reduced power consumption, low reflection, high color reproducibility, and high light extraction efficiency and brightness with the same power consumption.

### BRIEF DESCRIPTION OF THE SEVERAL VIEWS OF THE DRAWINGS

The accompanying drawings, which are included to provide a further understanding of the disclosure and are incorporated in and constitute a part of this application, illustrate embodiments of the disclosure and together with the description serve to explain the principle of the disclosure. In the drawings:

FIG. 1 is a plan view illustrating an overall schematic structure of a light emitting display device according to an exemplary aspect of the present disclosure.

FIG. 2 is a circuit diagram of one sub-pixel included in the light emitting display device according to an exemplary aspect of the present disclosure.

FIG. 3 is a plan view illustrating a structure of one sub-pixel included in the light emitting display device according to an exemplary aspect of the present disclosure.

FIG. 4 is an enlarged cross-sectional view, along the cutting line I-I′ in FIG. 3, illustrating a structure of a bottom emission type light emitting display device according to an exemplary aspect of the present disclosure.

FIG. 5 is an enlarged cross-sectional view, along the cutting line II-II′ in FIG. 1, illustrating a structure of a bottom emission type light emitting display device according to an exemplary aspect of the present disclosure.

FIG. 6 is an enlarged cross-sectional view, along the cutting line III-III′ in FIG. 1, illustrating a structure of a bottom emission type light emitting display device according to an exemplary aspect of the present disclosure.

FIG. 7 is an enlarged plan view illustrating a structure of one sub-pixel included in a light emitting display device according to another exemplary aspect of the present disclosure.

### DETAILED DESCRIPTION

Advantages and features of the present disclosure, and implementation methods thereof will be clarified through following embodiments described with reference to the accompanying drawings. The present disclosure may, however, be embodied in different forms and should not be construed as limited to the embodiments set forth herein. Rather, these example embodiments are provided so that this disclosure may be sufficiently thorough and complete to assist those skilled in the art to fully understand the scope of the present disclosure. Further, the protected scope of the present disclosure is defined by claims and their equivalents.

The shapes, sizes, dimensions (e.g., length, width, height, thickness, radius, diameter, area, etc.), ratios, angles, numbers, and the like, which are illustrated in the drawings in order to describe various example embodiments of the present disclosure, are merely given by way of example.

A dimension including size and a thickness of each component illustrated in the drawing are illustrated for convenience of description, and the present disclosure is not limited to the size and the thickness of the component illustrated, but it is to be noted that the relative dimensions including the relative size, location, and thickness of the components illustrated in various drawings submitted herewith are part of the present disclosure.

Therefore, the present disclosure is not limited to the illustrated details. Like reference numerals refer to like elements throughout the specification unless otherwise specified. In the following description, where the detailed description of the relevant known function or configuration may unnecessarily obscure an important point of the present disclosure, a detailed description of such known function of configuration may be omitted.

Reference will now be made in detail to the exemplary embodiments of the present disclosure, examples of which are illustrated in the accompanying drawings. Wherever possible, the same reference numbers will be used throughout the drawings to refer to the same or like parts. In the specification, it should be noted that like reference numerals already used to denote like elements in other drawings are used for elements wherever possible. In the following description, when a function and a configuration known to those skilled in the art are irrelevant to the essential configuration of the present disclosure, their detailed descriptions will be omitted. The terms described in the specification should be understood as follows.

In the present specification, where the terms “comprise,” “have,” “include,” and the like are used, one or more other elements may be added unless the term, such as “only,” is used. An element described in the singular form is intended to include a plurality of elements, and vice versa, unless the context clearly indicates otherwise.

In construing an element, the element is construed as including an error or tolerance range even where no explicit description of such an error or tolerance range is provided.

In the description of the various embodiments of the present disclosure, where positional relationships are described, for example, where the positional relationship between two parts is described using “on,” “over,” “under,” “above,” “below,” “beside,” “next,” or the like, one or more other parts may be located between the two parts unless a more limiting term, such as “immediate(ly),” “direct(ly),” or “close(ly)” is used. For example, where an element or layer is disposed “on” another element or layer, a third layer or element may be interposed there-between. Also, if a first element is described as positioned “on” a second element, it does not necessarily mean that the first element is positioned above the second element in the figure. The upper part and the lower part of an object concerned may be changed depending on the orientation of the object. Consequently, where a first element is described as positioned “on” a second element, the first element may be positioned “below” the second element or “above” the second element in the figure or in an actual configuration, depending on the orientation of the object.

In describing a temporal relationship, when the temporal order is described as, for example, “after,” “subsequent,” “next,” or “before,” a case which is not continuous may be included unless a more limiting term, such as “just,” “immediate(ly),” or “direct(ly),” is used.

It will be understood that, although the terms “first,” “second,” and the like may be used herein to describe various elements, these elements should not be limited by these terms as they are not used to define a particular order. These terms are used only to distinguish one element from another. For example, a first element could be termed a second element, and, similarly, a second element could be termed a first element, without departing from the scope of the present disclosure.

In describing the components of the present disclosure, terms such as ‘first’, ‘second’, ‘A’, ‘B’, ‘(a)’ and ‘(b)’ may be used. These terms are only used to distinguish the components from other components, and the nature, sequence, order or number of the corresponding component is not limited by the term. Where an element is described as being “linked”, “coupled,” or “connected” to another element, that element may be directly or indirectly connected to that other element unless otherwise specified. It is to be understood that additional element or elements may be “interposed” between the two elements that are described as “linked,” “connected,” or “coupled” to each other.

It should be understood that the term “at least one” should be understood as including any and all combinations of one or more of the associated listed items. For example, the meaning of “at least one of a first element, a second element, and a third element” encompasses the combination of all three listed elements, combinations of any two of the three elements, as well as each individual element, the first element, the second element, and the third element.

Features of various embodiments of the present disclosure may be partially or overall coupled to or combined with each other, and may be variously inter-operated with each other and driven technically as those skilled in the art can sufficiently understand. The embodiments of the present disclosure may be carried out independently from each other, or may be carried out together in a co-dependent relationship.

Hereinafter, an example of a display apparatus according to the present disclosure will be described in detail with reference to the attached drawings. Wherever possible, the same reference numbers will be used throughout the drawings to refer to the same or like parts. Since a scale of each of elements shown in the accompanying drawings may be different from an actual scale for convenience of description, the present disclosure is not limited to the scale shown in the drawings.

Hereinafter, referring to the attached figures, the present disclosure will be explained. The scales of the elements shown in the drawings have different scales from actual ones for convenience of explanation, so they are not limited to the scales shown in the drawings.

FIG. 1 is a plan view illustrating an overall schematic structure of a light emitting display according to an embodiment of the present disclosure. In FIG. 1, X-axis refers to the direction parallel to the scan line, Y-axis refers to the direction of the data line, and Z-axis refers to the height direction of the display device.

Referring to FIG. 1, a light emitting display device comprises a substrate 110, a gate (or scan) driver 200, a pad portion 300, a source driving IC (Integrated Circuit) 410, a flexible circuit film 430, a circuit board 450, and a timing controller 500.

The substrate 110 may include an electrical insulating material or a flexible material. The substrate 110 may be made of a glass, a metal or a plastic, but it is not limited thereto. When the light emitting display device is a flexible display device, the substrate 110 may be made of the flexible material such as plastic. For example, the substrate 110 may include a transparent polyimide material.

The substrate 110 may include a display area AA and a non-display area NDA. The display area AA, which is an area for representing the video images, may be defined as the majority middle area of the substrate 110, but it is not limited thereto. In the display area AA, a plurality of scan lines SL (or gate lines), a plurality of data lines DL and a plurality of pixels P may be formed or disposed.

Here, each pixel P may include a first subpixel SP1, a second subpixel SP2 and a third subpixel SP3. However, it is not limited thereto, each pixel P may include a first subpixel SP1, a second subpixel SP2, a third subpixel SP3 and a fourth subpixel. For example, the first subpixel SP1 may be a red subpixel, the second subpixel SP2 may be a green subpixel, and the third subpixel SP3 may be a blue subpixel.

Each of subpixels SP1, SP2 and SP3 may include an emission area EA and a non-emission area NEA. The emission area EA may be defined as an area where light for displaying a video image is generated. The non-emission area NEA may be defined as an area where light to display an image is not generated. Further, the area excluding the emission area EA in the subpixels SP1, SP2 and SP3 may be defined as the non-emission area NEA. The non-emission area NEA may be disposed as surrounding the emission area EA. The emission area EA may be an area where the light emitting element is disposed. The non-emission area NEA may be an area where the driving element and signal lines for driving the light emitting element.

The non-display area NDA, which is an area not representing the video images, may be defined at the circumference areas of the substrate 110 surrounding all or some of the display area AA. In the non-display area NDA, the gate driver 200 and the pad portion 300 may be formed or disposed.

The gate driver 200 may supply the scan (or gate) signals to the scan lines according to the gate control signal received from the timing controller 500 through the pad portion 300. The gate driver 200 may be formed at the non-display area NDA disposed at a circumferential area of the display area AA on the substrate 110, as a GIP (Gate driver In Panel) type. GIP type means that the gate driver 200 is directly formed on the substrate 110. For example, the gate driver 200 may include a shift register. The GIP type refers to a structure in which transistors included in the shift register of the gate driver 200 are formed directly on the substrate 110.

The pad portion 300 may supply data signals to the data lines DL according to the data control signal received from the timing controller 500. The source driving IC 410 made of a driving chip may be mounted on the flexible circuit film 430, and may be attached on the pad portion 300 outside one side of the display area AA of the substrate 110 using a TAB (tape automated bonding) method.

The source driving IC 410 may receive the digital video data and the source control signal from the timing controller 500. The source driving IC 410 may convert the digital video data into the analog data voltages according to the source control signal and then supply that to the data lines. When the source driving IC 410 is made as a chip type, it may be installed on the flexible circuit film 430 as a COF (Chip On Film) or COP (Chip On Plastic) type.

The flexible circuit film 430 may include a plurality of first link lines connecting the pad portion 300 to the source driving IC 410, and a plurality of second link lines connecting the pad portion 300 to the circuit board 450. The flexible circuit film 430 may be attached on the pad portion 300 using an anisotropic conducting film, so that the pad portion 300 may be connected to the first link lines of the flexible circuit film 430.

The circuit board 450 may be attached to the flexible circuit film 430. The circuit board 450 may include a plurality of circuits implemented as the driving chips. For example, the circuit board 450 may be a printed circuit board or a flexible printed circuit board.

The timing controller 500 may receive the digital video data and the timing signal from an external system board through the line cables of the circuit board 450. The timing controller 500 may generate a gate control signal for controlling the operation timing of the gate driver 200 and a source control signal for controlling the source driving IC 410, based on the timing signal. The timing controller 500 may supply the gate control signal to the gate driver 200 and supply the source control signal to the source driving IC 410. Depending on the product types, the timing controller 500 may be formed as one chip with the source driving IC 410 and mounted on the substrate 110.

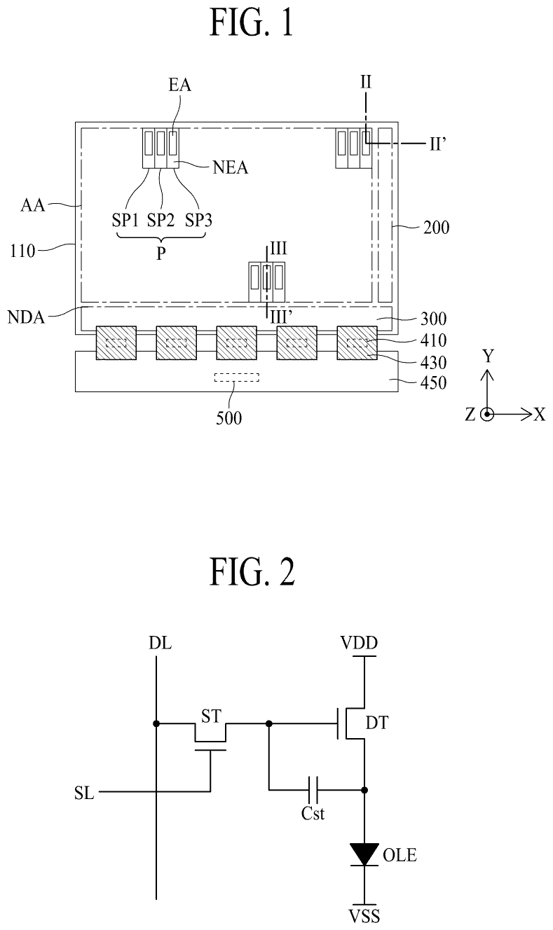

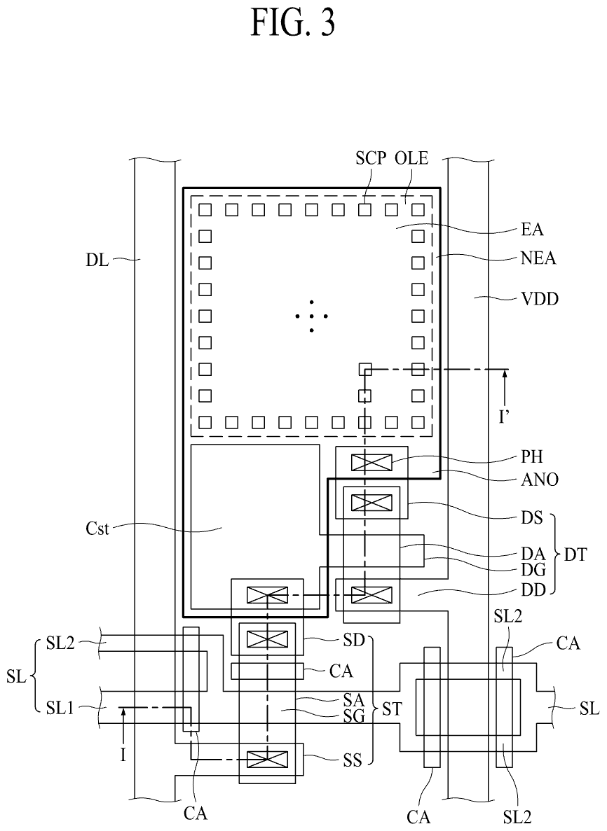

Hereinafter further referring to FIGS. 2 to 4, a light emitting display device according to an exemplary aspect of the present disclosure will be described. FIG. 2 is a circuit diagram of one sub-pixel included in the light emitting display device according to an exemplary aspect of the present disclosure. FIG. 3 is a plan view illustrating a structure of one sub-pixel included in the light emitting display device according to an exemplary aspect of the present disclosure.

At first, referring to FIGS. 2 and 3, a light emitting display device according to the present disclosure includes a plurality of pixels P arrayed in a matrix manner. Each pixel P may include at least three sub-pixels SP. Each sub-pixel SP of the light emitting display device may be defined by a scan line SL, a data line DL and a driving current line VDD. One sub-pixel SP of the light emitting display device may include a switching thin film transistor ST, a driving thin film transistor DT, a light emitting diode OLE and a storage capacitance Cst. The driving current line VDD may be supplied with a high-level voltage for driving the light emitting diode OLE.

In the light emitting display device according to the present disclosure, the scan line SL may be partially separated into two branches. The scan line SL may run in the X-axis direction, and the data line DL and the driving current line VDD may run in the Y-axis direction. Accordingly, a portion of the scan line SL may intersect the data line DL and the driving current line VDD. At this intersection portion, the scan line SL may be disconnected. In order to recover (or repair) this disconnection, the scan line SL may be branched into a first scan line SL1 and a second scan line SL2.

For example, when the first scan line SL1 may be disconnected or broken, the gate signal may be transferred to the gate line SL and gate electrode via the second scan line SL2. For another case, when a short circuit occurs between the first scan line SL1 and the data line DL or the driving current line VDD, the short circuit problem may be solved by cutting both ends of the first scan line SL1 where they are connected to or branched from the scan line SL. For this recovery process, a cutting area CA may be defined at a portion where the scan line SL is separated into the first scan line SL1 and the second scan line SL2. When it is necessary, that is when a short circuit problem occurs, the first scan line SL1 or the second scan line SL2 may be separated from the scan line SL by irradiating a laser to the cutting area CA.

The switching thin film transistor ST may be disposed at the portion where the scan line SL and the data line DL is crossing. The switching thin film transistor ST may include a gate electrode SG, a semiconductor layer SA, a source electrode SS and a drain electrode SD. The gate electrode SG of the switching thin film transistor ST may be one portion of the scan line SL. The semiconductor layer SA may be disposed as crossing the gate electrode SG. The overlapped portions of the semiconductor layer SA with the gate electrode SG may be defined as the channel area. The source electrode SS may be connected to or branched from the data line DL and the drain electrode SD may be connected to the driving thin film transistor DT. One side of the semiconductor layer SA is connected to the source electrode SS, and the other side of the semiconductor layer SA is connected to the drain electrode SD. By supplying the data signal to the driving thin film transistor DT, the switching thin film transistor ST may play a role of selecting a pixel which would be driven.

The driving thin film transistor DT may play a role of driving the light diode OLE of the selected pixel by the switching thin film transistor ST. The driving thin film transistor DT may include a gate electrode DG, a semiconductor layer DA, a source electrode DS and a drain electrode DD. The gate electrode DG of the driving thin film transistor DT may be connected to the drain electrode SD of the switching thin film transistor ST. For example, the gate electrode DG of the driving thin film transistor DT may be connected to or extended from the drain electrode SD of the switching thin film transistor ST. In the driving thin film transistor DT, the drain electrode DD is connected to or branched from the driving current line VDD, and the source electrode DS is connected to a pixel electrode ANO (or anode electrode) of the light emitting diode (or light emitting element) OLE. The semiconductor layer DA may be disposed as crossing the gate electrode DG. The overlapped area of the semiconductor layer DA with the gate electrode DG may be defined as a channel area. The source electrode DS is connected to one side of the semiconductor layer DA, and the drain electrode DD is connected to the other side of the semiconductor layer DA. A storage capacitance Cst may be disposed between the gate electrode DG of the driving thin film transistor DT and the anode electrode ANO of the light emitting diode OLE.

The driving thin film transistor DT may be disposed between the driving current line VDD and the light emitting diode OLE. The driving thin film transistor DT may control the amount of currents flowing from the driving current line VDD to the light emitting diode OLE according to the difference voltage between the gate electrode DG and the source electrode DS.

The light emitting diode OLE may include a pixel electrode ANO, (or anode electrode) an emission layer EL and a common electrode CAT (or cathode electrode). The light emitting diode OLE may display an image by emitting light according to a current controlled by the driving thin film transistor DT. The pixel electrode ANO of the light emitting diode OLE is connected to the source electrode DS of the driving thin film transistor DT, and the common electrode CAT is connected to the low-power line VSS to which a low-level voltage is suppled. Accordingly, the light emitting diode OLE is driven by the current flowing from the driving current line VDD to the low-power line VSS in accordance with the operation of the driving thin film transistor DT.

In FIGS. 2 and 3, the case where a driving element for driving the light emitting diode OLE may include two thin film transistors and one capacitor is used. However, it is not limited thereto, the driving element may include three thin film transistors and one capacitor. For example, the three thin film transistors may include a driving thin film transistor, a switching thin film transistor and a compensation thin film transistor depending on their function. The driving thin film transistor may supply a driving current based on the data voltage to the light emitting diode. The switching thin film transistor may supply the data voltage from the data line to the driving thin film transistor as responding to the scan signal. The compensation thin film transistor may compensate for changes in characteristics values of the driving thin film transistor in response to the scan signal. The capacitor may store the gate-source voltage or gate-drain voltage of the driving thin film transistor.

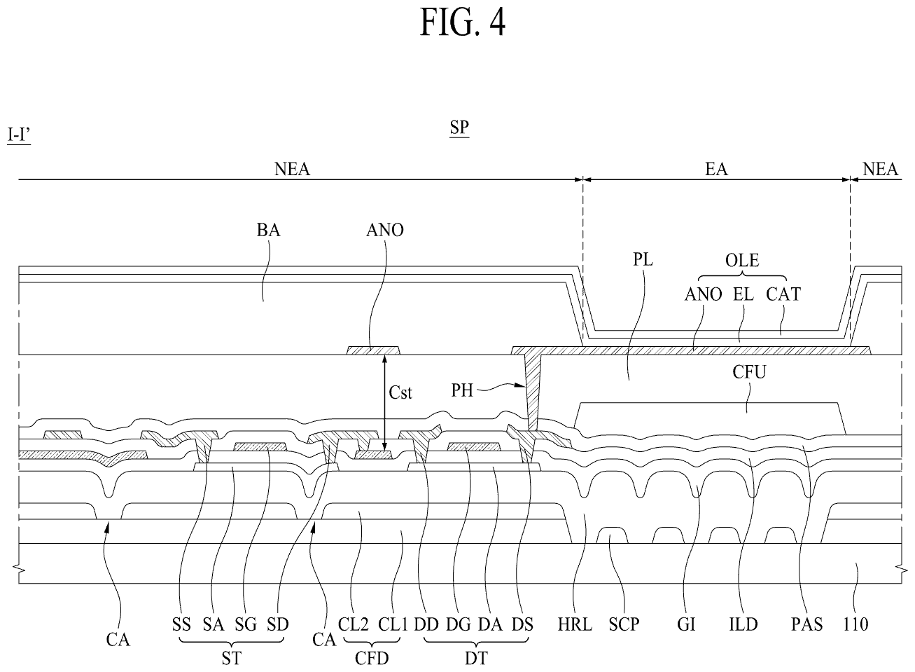

Further referring to FIG. 4, the cross sectional structure of the light emitting display device according to the present disclosure will be explained. FIG. 4 is an enlarged cross-sectional view, along the cutting line I-I′ in FIG. 3, illustrating a structure of a bottom emission type light emitting display device according to an exemplary aspect of the present disclosure.

A lower color filter CFD may be disposed on a substrate 110. The lower color filter CFD may be arranged to correspond to the non-emission area NEA in the subpixel SP. The lower color filter CFD may include a first color layer CL1 and a second color layer CL2 sequentially stacked each other. However, it is not limited thereto, the lower color filter CFD may further include a third color layer on the first color layer CL1 and the second color layer CL2. Here, each of the first color layer CL1, the second color layer CL2 and the third color layer may include one color allocated to any subpixel included in the display device.

When the display device includes a red subpixel, a green subpixel, and a blue subpixel, each of the first color layer CL1, the second color layer CL2 and the third color layer may be any one of red, green and blue, and they are different color from each other. For example, the first color layer CL1 may include a color material having a red wavelength band, the second color layer CL2 may include a color material having a green wavelength band, and the third color layer may include a color material having a blue wavelength band. Here, the red wavelength band may have a range from 620 nm to 780 nm, and may typically be a wavelength of 700 nm. The green wavelength band may have a range from 490 nm to 570 nm, and may typically be a wavelength of 550 nm. The blue wavelength band may have a range from 430 nm to 490 nm, and may typically be a wavelength of 450 nm.

In addition, a scattering pattern SCP may be disposed in an area corresponding to the emission area EA, at the same layer as the lower color filter CFD. The scattering pattern SCP may have a shape in which a plurality of small square shapes (or rectangles) may be scattered within the emission area EA. The scattering pattern SCP may be irregularly scattered or regularly arrayed in a matrix manner as shown in FIG. 3. The scattering pattern SCP may be any one of the first color layer CL1, the second color layer CL2 and the third color layer. For example, the scattering pattern SCP disposed in the red subpixel may include a color material having the red wavelength band. The scattering pattern SCP disposed in the green subpixel may include a color material having the green wavelength band. In addition, the scattering pattern SCP disposed in the blue subpixel may include a color material having the blue wavelength band.

Further, at the area corresponding to the cutting area CA, only one color layer of the first color layer CL1 and the second color layer CL2 is disposed. For example, at the cutting area CA, the first color layer CL1, the lower layer, may be disposed but the second color layer CL2, the upper layer, may be removed. Here, the color layer disposed in the cutting area CA may have a color wavelength range that may pass the laser irradiated to the cutting area CA. For example, when a green laser may be used for the cutting process, the first color layer CL1 disposed at the cutting area CA may include a color material having the green wavelength band. For another example, when a blue laser may be used for the cutting process, the first color layer CL1 disposed at the cutting area CA may include a color material having the blue wavelength band.

At the non-emission area NEA, a lower color filter CFD having at least two different color layers stacked each other are disposed. At the emission area EA, a scattering pattern SCP including color material having the color wavelength band corresponding to the color filter allocated to the subpixel may be disposed.

A transparent insulating layer HRL may be disposed on the substrate 110 having the lower color filter CFD and the scattering pattern SCP. The transparent insulating layer HRL may be a buffer layer. The transparent insulating layer HRL may have a transparency with a light transmittance of 95% or more.

A semiconductor layer SA of the switching thin film transistor ST and a semiconductor layer DA of the driving thin film transistor DT may be formed on the transparent insulating layer HRL. It is not shown in figures, an additional buffer layer may be further disposed between the semiconductor layers SA and DA and the substrate 110.

A gate insulating layer GI may be disposed on the semiconductor layers SA and DA and the substrate 110. A gate electrode SG of the switching thin film transistor ST and a gate electrode DG of the driving thin film transistor DT may be formed on the gate insulating layer GI. The gate electrode SG of the switching thin film transistor ST may be disposed as overlapping the semiconductor layer SA of the switching thin film transistor ST. The overlapped area of the semiconductor layer SA with the gate electrode SG of the switching thin film transistor ST may be defined as the channel area. The gate electrode DG of the driving thin film transistor DT may be disposed as overlapping the semiconductor layer DA of the driving thin film transistor DT. The overlapped area of the semiconductor layer DA with the gate electrode DG of the driving thin film transistor DT may be defined as the channel area.

An intermediate insulating layer ILD is deposited on the gate electrodes SG and DG and the gate insulating layer GI. Source-drain electrodes are formed on the intermediate insulating layer ILD. In detail, a source electrode SS of the switching thin film transistor ST contacting to one side of the semiconductor layer SA of the switching thin film transistor ST, and a drain electrode SD of the switching thin film transistor ST contacting to another side of the semiconductor layer SA of the switching thin film transistor ST may be formed. Further, a source electrode DS of the driving thin film transistor DT contacting to one side of the semiconductor layer DA of the driving thin film transistor DT, and a drain electrode DD of the driving thin film transistor DT contacting to another side of the semiconductor layer DA of the driving thin film transistor DT may be formed.

The source electrode SS of the switching thin film transistor ST may be branched from the data line DL. The drain electrode DD of the driving thin film transistor DT may be branched from the driving current line VDD. The drain electrode SD of the switching thin film transistor ST may be connected to the gate electrode DG of the driving thin film transistor DT via a drain contact hole formed at the intermediate insulating layer ILD.

On the substrate 110 having the thin film transistors ST and DT, a passivation layer PAS may be deposited. The passivation layer PAS preferably is made of an inorganic material such as silicon oxide (SiOx) or silicon nitride (SiNx). A upper color filter CFU may be disposed at the area corresponding to the emission area EA on the passivation layer PAS. The upper color filter CFU may be slightly larger than and overlapped with the pixel electrode ANO which may be formed later.

The upper color filter CFU may be any one of the first color layer CL1, the second color layer CL2 and the third color layer. For example, the scattering pattern SCP disposed in the red subpixel may include a color material having the red wavelength band. The scattering pattern SCP disposed in the green subpixel may include a color material having the green wavelength band. In addition, the scattering pattern SCP disposed in the blue subpixel may include a color material having the blue wavelength band. Specifically, the upper color filter CFU may have the color material having the same color wavelength band as the color of the scattering pattern SCP.

The thickness of the scattering pattern SCP may be same with or thinner than that of the lower color filter CFD. For example, when the lower color filter CFD may have two color layers, the scattering pattern SCP may have one color layer, so the thickness of the scattering pattern SCP may be thinner than that of the lower color filter CFD. For another example, when the lower color filter CFD has one color layer, the thickness of the scattering pattern SCP may be same with the lower color filter CFD. In this case, the thickness of the scattering pattern SCP may be slightly thinner than that of the lower color filter CFD during the patterning process.

In the plan view, the area of the scattering pattern SCP may be same as or slightly smaller than the emission area EA. Otherwise, the area having the scattering pattern SCP may be same as or slightly smaller than the area of the upper color filter CFU. However, it is not limited thereto, the area having the scattering pattern SCP may be slightly larger than the upper color filter CFU.

A planarization layer PL may be disposed on the passivation layer PAS and the upper color filter CFU. The planarization layer PL may be used to flatten the uneven surface condition of the substrate 110 on which the thin film transistors ST and DT are formed. In order to equalize the height difference due to the uneven surface condition, the planarization layer PL may be formed of an organic material. A pixel contact hole PH may be formed at the passivation layer PAS and the planarization layer PL for exposing some of the source electrode DS of the driving thin film transistor DT.

A pixel electrode ANO is formed on the top surface of the planarization layer PL. The pixel electrode ANO is connected to the source electrode DS of the driving thin film transistor DT via the pixel contact hole PH. Depending to the emission type, the pixel electrode ANO may have different materials or elements. For the bottom emission type, the pixel electrode ANO may include a transparent conductive material. For the top emission type in which the light is provided to the upper side facing the substrate 110, the pixel electrode ANO may include a metal material having excellent light reflectance. FIG. 4 shows the bottom emission type structure.

A bank BA is formed on the pixel electrode ANO. The bank BA covers the circumferential areas of the pixel electrode ANO and exposes the middle portions of the pixel electrode ANO. The middle portions of the pixel electrode ANO exposed from the bank BA may be defined as the emission area EA. The bank BA may be disposed as covering the non-emission area NEA.

An emission layer EL is deposited on the substrate 110 having the pixel electrode ANO and the bank BA. The emission layer EL may be formed on the pixel electrode ANO and the bank BA as covering entire display area AA of the substrate 110.

A common electrode CAT may be disposed on the emission layer EL. The common electrode CAT may be formed as one layer continuing over a plurality of pixels P on the substrate 110. For example, the common electrode CAT may have one sheet layer stacked covering the whole surface of the display area AA. When required, the common electrode CAT may be covering whole of the display area AA and extended to the non-display area NDA. It is not shown in figures, an encapsulation layer may be further disposed on the common electrode CAT. The encapsulation layer may have one layered structure, or a multiple-layered structure having organic layers and inorganic layers stacked alternately each other.

Referring to the cross-sectional structure of the light emitting display device according to the present disclosure, the substrate 110 may include a display area AA and a non-display area NDA. The display area AA may include an emission area EA and a non-emission area NEA. In detail, the display area AA may include a plurality of pixels P. Each pixel P may include a first subpixel SP1, a second subpixel SP2 and a third subpixel SP3. The emission area EA may include an upper color filter CFU having any one color layer among at least three color layers such as a first color layer, a second color layer and a third color layer used for representing video images. The non-emission area NEA may include a lower color filter CFD having stacked two color layers including at least two different color layers among the three color layers such as the first color layer, the second color layer and the third color layer used for representing video images.

Since the lower color filter CFD configured with at least two different color layers is disposed in the non-emission area NEA, external light incident from the outside may not pass through the lower color filter CFD but may be absorbed by the lower color filter CFD. That is, the reflection of external light by the metal material disposed in the non-emission area NEA may be suppressed. As a result, the problem of image information provided from the emission area EA may be prevented from being distorted by the reflection of external light.

For an example, the first color layer CL1 for the lower color filter CFD may be blue, and the second color layer CL2 may be red. For another example, the first color layer CL1 for the lower color filter CFD may be green and the second color layer CL2 may be red or blue. For still another example, the lower color filter CFD may be made by stacking three color layers used in the display device. In any case, the upper color filter CFU may be any one of red, green and blue.

In the emission area EA, a scattering pattern SCP having the same color material as the upper color filter CFU may be disposed on the same layer as the lower color filter CFD under the upper color filter CFU. When external light is incident into the emission area EA, the external light may be scattered by the scattering pattern SCP, so the amount of light reflected by the common electrode CAT of the emission area EA may be remarkably reduced.

Further, the transparent insulating layer HRL having higher refractive index than the upper color filter CFU may be disposed under the upper color filter CFU. For example, the refractive index of the upper color filter CFU may be 1.4˜1.6 (in some examples, 1.5). The transparent insulating layer HRL may be formed of a transparent insulating material with a refractive index of 1.8 to 1.9 (in some examples, 1.9). In this case, as passing through the upper color filter CFU, (i.e., a lower refractive layer) and the transparent insulating layer HRL (i.e., a higher refractive layer), the light provided from the emission layer EL may be concentrated. Therefore, the colors from neighboring subpixels may not be mixed, so the color purity may be improved. As a result, image quality degradation due to external light reflection may be prevented and image information with high color purity may be provided.

Furthermore, in the lower color filter CFD, only one specific color layer may remain corresponding to the cutting area CA. In this case, the color layer disposed at the cutting area CA may include a color material having a wavelength corresponding to the wavelength of the laser used in the repair process (or cutting process). The laser used in the repair process may be transmitted only to the cutting area CA to perform the cutting process. When the laser is irradiated to an area other than the cutting area CA, the laser may not pass through the lower color filter CFD due to the color layer having a different color from the laser. Therefore, it is possible to prevent unexpected problems such as disconnection of normal lines due to incorrect laser irradiation during the repair process.

In the light emitting display device according to the present disclosure described above, the lower color filter CFD disposed in the non-emission area NEA may include stacked two color layers having different color from each other, i.e., the first color layer CL1 and the second color layer CL2. However, it is not limited thereto, any one color layer may be disposed. In this case, the lower color filter CFD may include a color material having a wavelength corresponding to the wavelength of the laser used in the repair process (or cutting process).

When the lower color filter includes two different color layers, the effect of suppressing external light reflection may be maximized. However, when a cutting area CA may be required, a pattern process may be added, so increasing the costs. On the contrary, when the lower color filter CFD may include one color layer, the effect of suppressing external light reflection may be somewhat degraded. However, since there is no need to perform a specific process for preparing the cutting area CA, the process may be simple and cost may not increase. Considering these conditions, the structure of the lower color filter CFD may be selected to suit the manufacturing process and product purpose.

In addition, the above description is focused on the structure in which the scattering pattern SCP may be arranged below the upper color filter CFU in the emission area EA. However, it is not limited thereto, the scattering pattern SCP may not be included. For another example, the scattering pattern SCP may be made of a transparent material. In this case, by forming a material with a different refractive index than the transparent insulating layer HRL, for example, a material with a lower refractive index than the transparent insulating layer HRL, the scattering effect may be added.

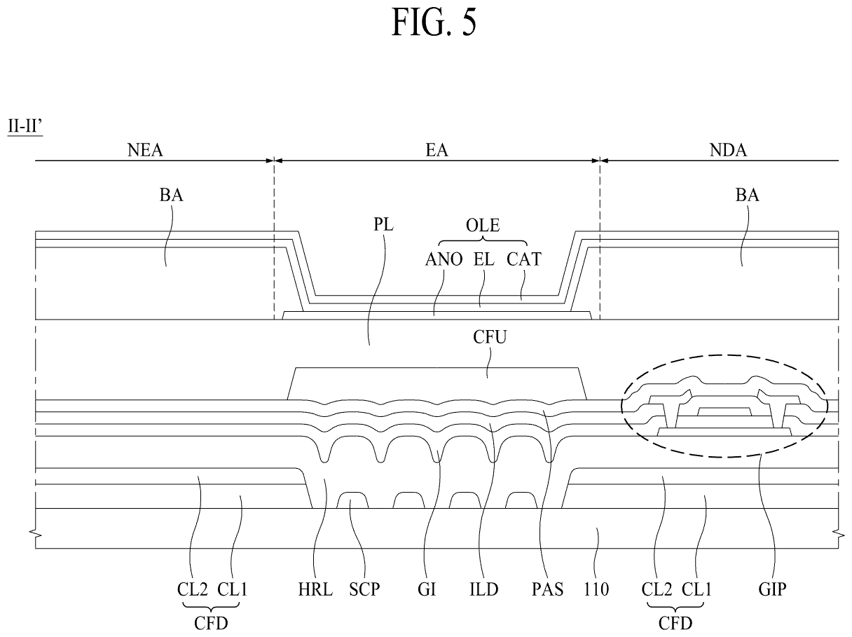

Hereinafter, referring to FIG. 5, a cross-sectional structure at the upper corner of the right side where the gate driver 200 may be located in the display device will be explained. FIG. 5 is an enlarged cross-sectional view, along the cutting line II-II′ in FIG. 1, illustrating a structure of a bottom emission type light emitting display device according to an exemplary aspect of the present disclosure.

Referring to FIG. 1 again, the substrate 110 of the light emitting display device according to the present disclosure includes a display area AA and a non-display area NDA. The display area AA may include a plurality of pixels P arrayed in a matrix manner. The non-display area NDA may be disposed at the upper outside and the right outside of the display area AA. The gate driver 200 may be disposed at the right outside of the display area AA. FIG. 5 shows a structure of the third subpixel SP3 and elements surrounding the third subpixel SP3 in the pixel P disposed at the right corner of the display area AA.

Referring to FIG. 5, the non-display areas NDA are disposed at the upper side and the right side of the third subpixel SP3. Between the non-display area NDA, the display area AA including the emission area EA of the third subpixel SP3 is disposed.

The lower color filter CFD may be disposed at the non-display area NDA on a substrate 110. The lower color filter CFD may include a first color layer CL1 and a second color layer CL2 sequentially stacked. A scattering pattern SCP may be disposed in the display area AA on the substrate 110.

A transparent insulating layer HRL may be disposed on the substrate 110 having the lower color filter CFD and the scattering pattern SCP. The transparent insulating layer HRL may be a buffer layer. The transparent insulating layer HRL may have a transparency of 95% or more.

In the display area AA on the transparent insulating layer HRL, even though it is not shown in FIG. 5, a switching thin film transistor ST and a driving thin film transistor DT may be formed. At the gate driver 200 disposed in the right side of the non-display area NDA, the gate driving element GIP may be formed on the transparent insulating layer HRL. The gate driving element GIP may have the same structure with the switching thin film transistor ST and the driving thin film transistor DT.

For example, the gate driving element GIP may include a semiconductor layer disposed on the transparent insulating layer HRL, a gate insulating layer GI covering the semiconductor layer, a gate electrode overlapped with the semiconductor layer on the gate insulating layer GI, an intermediate insulating layer ILD covering the gate electrode, a source electrode contacting one side of the semiconductor layer on the intermediate insulating layer ILD, a drain electrode contacting another side of the semiconductor layer on the intermediate insulating layer ILD, and a passivation layer PAS covering the source-drain electrodes, sequentially stacked.

A planarization layer PL extended from the display area AA may be disposed on the gate driving element GIP. A bank BA may be formed on the planarization layer PL.

The emission layer EL and the common electrode CAT disposed in the display area AA may be extended to the non-display area NDA. However, it is not limited thereto, the emission layer EL and the common electrode CAT may be extended only to some parts of the non-display area NDA. Especially, the common electrode CAT may extend further than the emission layer EL and may be formed to completely cover the emission layer EL.

Referring to FIG. 5, in display area AA, the light emitting diode OLE may be disposed at the emission area EA. The upper color filter CFU may be disposed under the light emitting diode OLE. The scattering pattern SCP may be disposed under the upper color filter CFU.

On the contrary, in the non-display area NDA, the lower color filter CFD may be disposed. Especially, the lower color filter CFD may be disposed under the elements including metal material such as the gate driving element GIP. As the result, light incident from outside may be absorbed by the lower color filter CFD. When there is reflected light by the metal material, the lower color filter CFD may absorb the reflected light. Therefore, the external light reflection may be effectively and remarkably suppressed. Accordingly, the lower color filter CFD may prevent the light information provided from the light emitting diode OLE from being distorted by the external light reflection.

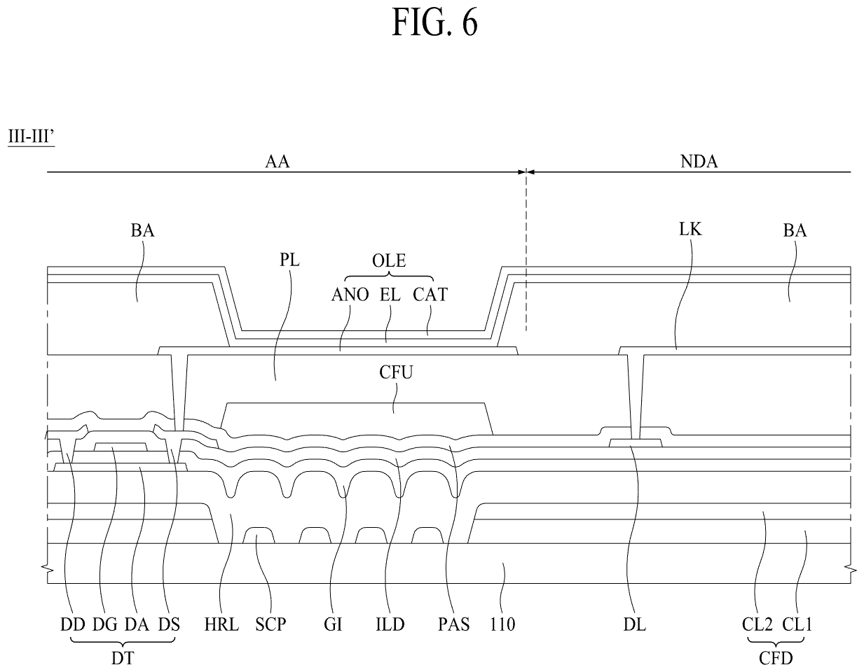

Hereinafter, referring to FIG. 6, a cross-sectional structure of the lower portion of the display device where the pad portion 300 is disposed will be explained. FIG. 6 is an enlarged cross-sectional view, along the cutting line III-III′ in FIG. 1, illustrating a structure of a bottom emission type light emitting display device according to an exemplary aspect of the present disclosure. In the following description for FIG. 6, elements same with the above description may be briefly explained or not duplicated.

Referring to FIG. 1 again, the substrate 110 of the light emitting display device according to the present disclosure includes a display area AA and a non-display area NDA. The display area AA may include a plurality of pixels P arrayed in a matrix manner. The non-display area NDA may be disposed at the lower outside of the display area AA. The pad portion 300 may be disposed at the non-display area NDA disposed at the lower side. FIG. 6 shows a structure of the second subpixel SP2 and elements surrounding the second subpixel SP2 in the pixel P disposed at the lower outside of the display area AA.

Referring to FIG. 6, the non-display area NDA may be disposed at the lower outside of the second subpixel SP2. The second subpixel SP2 may have the same structure as explained in FIG. 4. Therefore, detailed structure of the second subpixel SP2 will not be duplicated.

In the non-display area NDA disposed at lower side of the substrate 110, the lower color filter CFD may be disposed on the substrate 110. The lower color filter CFD may include the first color layer CL1 and the second color layer CL2 stacked sequentially.

The transparent insulating layer HRL may be deposited on the substrate 110 having the lower color filter CFD. The transparent insulating layer HRL may be a buffer layer. The transparent insulating layer HRL may have a transparency of 95% or more.

The data line DL may be extended to the pad portion 300 disposed in the non-display area NDA located at the lower side of the substrate 110, on the transparent insulating layer HRL. A link line LK may be connected to the end of the data line DL. The data line DL is shown in FIG. 6 for convenience, a data pad may be disposed at the end of the data line DL, and the data pad may be connected to the link line LK. The link line LK may include a link pad connected to the flexible circuit film attached to the pad portion 300. In FIG. 6, the data line DL and the some portion of the link line LK are shown.

On the transparent insulating layer HRL, the gate insulating layer GI and the intermediate insulating layer ILD may be sequentially deposited. On the intermediate insulating layer ILD, the data line DL connected to the source electrode SS of the switching thin film transistor ST may be disposed. In FIG. 6, only the driving thin film transistor DT connected to the light emitting diode OLE is shown. The structure of the switching thin film transistor ST may be referred to FIG. 4.

The passivation layer PAS may be deposited on the data line DL. The planarization layer PL may be deposited on the passivation layer PAS. The link line LK may be disposed on the planarization layer. The link line LK may be made of the same material and be disposed on the same layer with the pixel electrode ANO. However, it is not limited thereto, the link line LK may be made of a metal material different from the pixel electrode ANO. Considering that the link line LK is an element for transmitting signals, it is desirable to make the link line LK of a metal material with low line resistance.

The bank BA may be formed on the link line LK. The emission layer EL and the common electrode CAT formed in the display area AA may be extended to the non-display area NDA. However, it is not limited thereto, the emission layer EL and the common electrode CAT may be extended only to some parts of the non-display area NDA. Especially, the common electrode CAT may extend further than the emission layer EL and may be formed to completely cover the emission layer EL.

Referring to FIG. 6, in the display area AA, the light emitting diode OLE may be disposed at the emission area EA. The upper color filter CFU may be disposed under the light emitting diode OLE. The scattering pattern SCP may be disposed under the upper color filter CFU.

On the contrary, in the non-display area NDA, the lower color filter CFD may be disposed. Especially, the lower color filter CFD may be disposed under the elements including metal material such as the link line LK. As the result, light incident from outside may be absorbed by the lower color filter CFD. When there is reflected light by the metal material, the lower color filter CFD may absorb the reflected light. Therefore, the external light reflection may be effectively and remarkably suppressed. Accordingly, the lower color filter CFD may prevent the light information provided from the light emitting diode OLE from being distorted by the external light reflection.

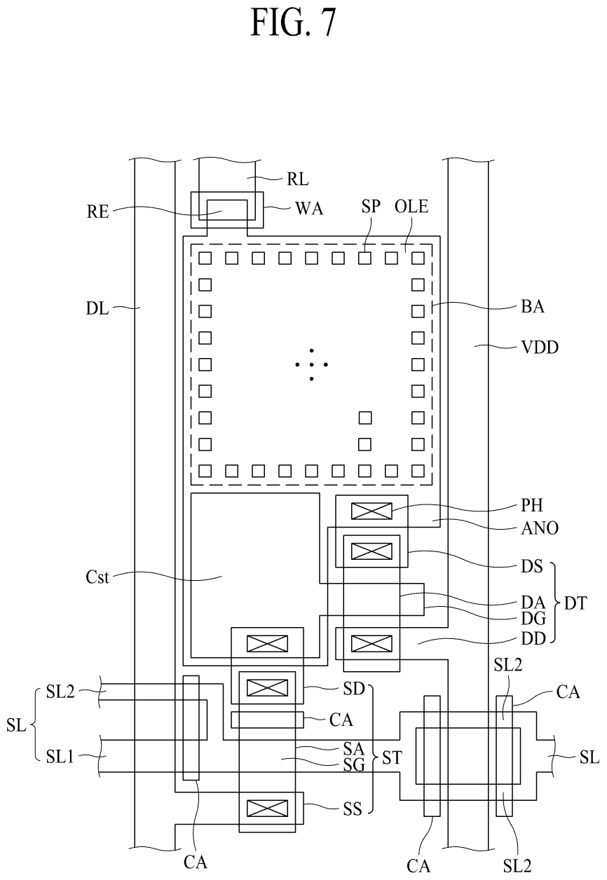

Hereinafter, referring to FIG. 7, the structure of a light emitting display device according to another exemplary aspect of the present disclosure will be explained. FIG. 7 is an enlarged plan view illustrating a structure of one sub-pixel included in a light emitting display device according to another exemplary aspect of the present disclosure. The structure of the light emitting display device according to another exemplary aspect may be very similar with the light emitting display device shown in FIG. 3.

The light emitting display device shown in FIG. 7 may include a repair electrode RE having the extruded shape from the pixel electrode ANO formed in the emission area EA to the non-emission area NEA. In addition, the light emitting display device shown in FIG. 7 may further include a repair line RL overlapping with the repair electrode RE and extended from the repair electrode RE to another pixel electrode.

When a driving element for driving any one subpixel SP is damaged, the semiconductor layer SA may be cut through the cutting area CA overlapping a portion of the semiconductor layer SA of the switching thin film transistor ST, so that the damaged driving element may be disconnected from the light emitting diode OLE. In this case, the light emitting diode OLE which was connected to the damaged driving element does not work so it may be treated as a ‘dark point’.

In some cases, the subpixel SP having the damaged driving element may not be proceeded as the dark point, but may be restored or recovered to operate like a normal subpixel by connecting with neighboring another subpixel SP having the same color. To do so, the repair line RL may be disposed between two subpixels SP, and each end portion of the repair line RL may be disposed as overlapping with the end portion of the repair electrode RE. That is, at least two subpixels SP assigned the same color may be configured as a pair sharing one repair line RL.

With this structure, when any one subpixel SP has a defection, the semiconductor layer SA of the subpixel SP may be disconnected by performing the cutting process to the cutting area CA overlapped with the semiconductor layer SA of the switching thin film transistor ST, so that the damaged driving element may be disconnected from the light emitting diode OLE. Further, the repair electrode RE disposed at the defective subpixel SP may be connected to the repair line RL, and the repair electrode RE of the normal subpixel SP paired with the defective subpixel SP may be connected to the repair line RL. As a result, the defective subpixel SP may be recovered to operate normally like the normal subpixel SP.

Here, a welding process in which a laser is irradiated to the repair electrode RE overlapping the repair line RL may be applied. To do so, a welding area WA may be set to the portion where the repair electrode RE is disposed in the non-emission area NEA. Since the welding area WA is disposed in the non-emission area NEA, the lower color filter CFD may overlap with the welding area WA. At the area corresponding to the welding area WA of the lower color filter CFD, only one of the first color layer CL1 and the second color layer CL2 may be disposed.

For example, the welding area WA may include the first color layer CL1 but not include the second color layer CL2. Here, the color layer disposed at the welding area WA may have a color wavelength band that may pass the wavelength of the laser irradiated to the welding area WA. For an example, when the blue laser may be used for the welding process, the first color layer CL1 disposed at the welding area WA may have a color material having the blue wavelength band. For another example, when the green laser may be used for the welding process, the first color layer CL1 disposed at the welding area WA may have a color material having the green wavelength band.

Other configurations are the same as those described in FIG. 3, so duplicate descriptions are omitted. The light emitting display device as shown in FIG. 7 may have the lower color filter CFD including at least two different color layers in the non-emission area NEA. The light incident from the outside may not pass through the lower color filter CFD and may be absorbed by the lower color filter CFD. Therefore, the external light reflection by the metal material disposed in the non-emission area NEA may be suppressed. Therefore, the distortion of image information provided from the emission area EA due to reflection of the external light may be prevented.

In addition, the lower color filter CFD may remain only one-color layer corresponding to the cutting area CA and the welding area WA. In this case, the color layer disposed at the cutting area CA and the welding area WA may be configured to include the color material with a wavelength corresponding to the wavelength of the laser used for the repair process. As a result, the laser used in the repair process may be transmitted only to the cutting area CA and/or the welding area WA so that the cutting process and/or the welding process may be performed. When the laser is irradiated to an area other than the cutting area CA and the welding area WA, the laser may not pass through the lower color filter CFD due to the color layer having a different color. Accordingly, it is desirable to prevent unexpected problems such as disconnection or melting of normal lines due to incorrect laser irradiation during the repair process.

The features, structures, effects and so on described in the above example embodiments of the present disclosure are included in at least one example embodiment of the present disclosure, and are not necessarily limited to only one example embodiment. Furthermore, the features, structures, effects and the like explained in at least one example embodiment may be implemented in combination or modification with respect to other example embodiments by those skilled in the art to which this disclosure is directed. Accordingly, such combinations and variations should be construed as being included in the scope of the present disclosure.

It will be apparent to those skilled in the art that various substitutions, modifications, and variations are possible within the scope of the present disclosure without departing from the spirit and scope of the present disclosure. Therefore, it is intended that embodiments of the present disclosure cover the various substitutions, modifications, and variations of the present disclosure, provided they come within the scope of the appended claims and their equivalents. These and other changes can be made to the embodiments in light of the above detailed description. In general, in the following claims, the terms used should not be construed to limit the claims to the specific example embodiments disclosed in the specification and the claims, but should be construed to include all possible embodiments along with the full scope of equivalents to which such claims are entitled. Accordingly, the claims are not limited by the disclosure.

The various embodiments described above can be combined to provide further embodiments. All of the U.S. patents, U.S. patent application publications, U.S. patent applications, foreign patents, foreign patent applications and non-patent publications referred to in this specification and/or listed in the Application Data Sheet are incorporated herein by reference, in their entirety. Aspects of the embodiments can be modified, if necessary to employ concepts of the various patents, applications and publications to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A light emitting display device comprising:
a substrate;
a display area including an emission area and a non-emission area;
a first color filter disposed in the emission area, the first color filter including at least one of a first color layer, a second color layer, and a third color layer;
a second color filter disposed in the non-emission area, the second color filter including at least one of the first color layer, the second color layer, and the third color layer;
a driving element disposed on the second color filter in the non-emission area; and
a light emitting element disposed on the first color filter in the emission area and electrically connected to the driving element.

2. The light emitting display device according to claim 1, wherein each of the first color layer, the second color layer, and the third color layer includes color material having different color wavelength band from each other.

3. The light emitting display device according to claim 2, wherein the first color layer includes a red wavelength band,
wherein the second color layer includes a green wavelength band, and
wherein the third color layer includes a blue wavelength band.

4. The light emitting display device according to claim 1, wherein the second color filter includes a blue color layer and a red color layer sequentially stacked.

5. The light emitting display device according to claim 1, wherein the second color filter includes a blue color layer and a green color layer sequentially stacked.

6. The light emitting display device according to claim 1, wherein the second color filter includes a red color layer and a green color layer sequentially stacked.

7. The light emitting display device according to claim 1, wherein the second color filter includes a red color layer, a green color layer, and a blue color layer sequentially stacked.

8. The light emitting display device according to claim 1, further comprising:
a transparent insulating layer disposed under the first color filter in the emission area; and
a scattering pattern disposed under the transparent insulating layer.

9. The light emitting display device according to claim 8, wherein the scattering pattern includes a color material same as the first color filter.

10. The light emitting display device according to claim 8, wherein the transparent insulating layer has a refractive index higher than the first color filter.

11. The light emitting display device according to claim 10, wherein the first color filter has a refractive index of 1.5, and
wherein the transparent insulating layer has a refractive index of 1.9.

12. The light emitting display device according to claim 1, wherein the driving element includes a repair portion, and
wherein the second color filter disposed at an area corresponding to the repair portion includes any one of the first color layer, the second color layer, and the third color layer.

13. The light emitting display device according to claim 12, wherein the color layer disposed at the area corresponding to the repair portion includes a color material having same wavelength with a laser irradiated to the repair portion.

14. The light emitting display device according to claim 1, further comprising:
a buffer layer disposed on the second color filter;
a thin film transistor disposed on the buffer layer;
a passivation layer disposed on the thin film transistor;
the first color filter disposed on the passivation layer;
a planarization layer disposed on the passivation layer and the first color filter;
a pixel electrode disposed on the planarization layer, electrically connected to the thin film transistor and corresponding to the emission area;
a bank disposed on the pixel electrode to define the emission area;
an emission layer disposed on the pixel electrode and the bank; and
a common electrode disposed on the emission layer.

15. The light emitting display device according to claim 14, further comprising:
a scattering pattern disposed at same layer with the second color filter and under the first color filter, and having same color with the first color filter.
